(19) United States
(12) Patent Application Publication
(10) Pub. No.: US 2026/0190932 A1
(43) Pub. Date: Jul. 2, 2026

(54) SUBSTRATE PROCESSING METHOD AND SUBSTRATE PROCESSING APPARATUS

(71) Applicant: SEMES CO., LTD., Cheonan-si (KR)

(72) Inventors: Jin Se PARK, Cheonan-si (KR); Seung Hoon OH, Cheonan-si (KR)

(73) Assignee: SEMES CO., LTD., Cheonan-si (KR)

(21) Appl. No.: 19/436,548

(22) Filed: Dec. 30, 2025

(30) Foreign Application Priority Data
Dec. 31, 2024 (KR) 10-2024-0202319

(51) Int. Cl. H10P 72/30; H10P 72/00

(52) U.S. Cl. CPC H10P 72/3302; H10P 72/0448; H10P 72/0606

(57) ABSTRACT

Provided is an apparatus for processing a substrate, the apparatus including: an index module including a load port and an index robot; and a treating module including a transfer frame including a buffer for temporarily storing a substrate, a liquid treating chamber for liquid-treating a substrate, a drying chamber for removing the liquid remaining on the substrate, and a transfer unit for transferring the substrate between the buffer, the liquid treating chamber, and the drying chamber, in which the transfer unit includes: a hand; a weight measuring unit for measuring a weight of the substrate; and a lifting driver configured to raise and lower the weight measuring unit relative to the hand.

### CROSS-REFERENCE TO RELATED APPLICATION

This application claims priority to and the benefit of Korean Patent Application No. 10-2024-0202319 filed in the Korean Intellectual Property Office on Dec. 31, 2024, the entire contents of which are incorporated herein by reference.

### TECHNICAL FIELD

The present invention relates to a substrate processing apparatus and method, and more particularly, to a substrate processing apparatus and method of liquid-treating a substrate.

### BACKGROUND ART

To manufacture a semiconductor device or liquid crystal display, various processes, such as photolithography, etching, ashing, ion implantation, and thin film deposition, are performed on a substrate. Before or after such a process proceeds, a cleaning process is performed to clean the substrate to remove contaminants and particles generated in each process. In general, the cleaning process includes a process of liquid-treating a substrate and a process of drying a substrate.

After the processing process is completed, the substrate is transferred from a liquid treating chamber to a drying chamber. In this case, when the amount of the organic solvent remaining on the substrate is greater than a preset range, the organic solvent acts as particles and contaminates the peripheral device. In contrast, when the amount of the organic solvent is less than the preset range, a process defect occurs due to a lining phenomenon of the pattern.

In addition, commonly used organic solvents are provided as highly volatile materials, and some of them may volatilize while the substrate is being transferred.

As a result, the weight of the substrate is measured to determine the amount of organic solvent (liquid) remaining on the substrate in the process of setting up the substrate processing facility and the like.

The method of measuring the weight of a substrate in the related art was performed in such a way that an operator directly measures the weight of the substrate. However, this method reduces the working efficiency of the substrate and has a problem that facility may be contaminated. In addition, while moving the substrate to measure the weight of the substrate, the liquid remaining on the substrate volatilized, making it difficult to accurately measure the weight of the substrate.

### SUMMARY OF THE INVENTION

The present invention has also been made in an effort to provide a substrate processing apparatus and a substrate processing method capable of automating a process of measuring weight of a substrate.

The present invention has also been made in an effort to provide a substrate processing apparatus and a substrate processing method capable of minimizing errors in measuring weight of a substrate.

The present invention has also been made in an effort to provide a substrate processing apparatus and a substrate processing method capable of increasing throughput by measuring the weight of the substrate during a substrate transfer process.

The objectives of the present disclosure are not limited thereto and other objectives not stated herein may be clearly understood by those skilled in the art from the following description.

An exemplary embodiment of the present disclosure, a substrate processing apparatus comprising: an index module including a load port and an index robot; and a treating module including a transfer frame including a buffer for temporarily storing a substrate, a liquid treating chamber for liquid-treating a substrate, a drying chamber for removing the liquid remaining on the substrate, and a transfer unit for transferring the substrate between the buffer, the liquid treating chamber, and the drying chamber, wherein the transfer unit may include: a hand; a weight measuring unit for measuring a weight of the substrate; and a lifting driver configured to raise and lower the weight measuring unit relative to the hand.

According to the exemplary embodiment of the present invention, wherein the weight measuring unit may include: a support on which the substrate is placed; a weight measuring sensor for measuring the weight of the substrate placed on the support; and a measuring device base for supporting the weight measuring sensor.

According to the exemplary embodiment of the present invention, wherein the support includes: a bottom plate; and a plurality of support protrusions protruding upward from the bottom plate and being in contact with a bottom surface of the substrate, and the plurality of support protrusions may be disposed to support the substrate at points spaced apart from each other.

According to the exemplary embodiment of the present invention, wherein a distance between two support protrusions adjacent to each other among the plurality of support protrusions may be smaller than a radius of the substrate.

According to the exemplary embodiment of the present invention, wherein the transfer unit further includes a base, and the base includes a frame having an inner space in which the weight measuring unit and the lifting driver are installed, the lifting driver raises and lowers the weight measuring unit between a weight measurement position and a standby position, the weight measurement position is where the weight measuring unit ascends and the support protrusions support the substrate, and the standby position is a position where the support protrusion may be disposed below the substrate supported by the hand.

According to the exemplary embodiment of the present invention, wherein the hand includes a pair of fingers supporting an edge of the substrate, and when the weight measuring unit moves from the standby position to the weight measurement position, the support protrusion and the finger may be disposed so as not to interfere with each other.

According to the exemplary embodiment of the present invention, wherein a plurality of through holes are formed on an upper surface of the frame, and the plurality of through holes may be respectively provided at points corresponding to the plurality of support protrusions when viewed from above.

According to the exemplary embodiment of the present invention, wherein the transfer frame further includes a fan unit that generates descending airflow in a transfer region therein, and the transfer unit further may include an airflow blocking plate disposed above the hand to block the descending airflow from reaching the substrate.

According to the exemplary embodiment of the present invention, further comprising: controller, the controller controls the weight measuring unit to measure the weight of the substrate while the transfer unit transfers the substrate, and the weight measurement of the substrate may be performed in a state where the weight measuring unit ascends from the standby position to the weight measurement position, the weight measuring unit takes over the substrate supported by the hand, and the support supports the substrate.

According to the exemplary embodiment of the present invention, wherein the controller may controls the transfer unit to measure the weight of the substrate before the substrate is loaded into the liquid treating chamber, and measure the weight of the substrate after the substrate is unloaded from the liquid treating chamber.

According to the exemplary embodiment of the present invention, wherein the substrate unloaded from the liquid treating chamber is a substrate on which a liquid film may be formed.

An exemplary embodiment of the present disclosure, a method of processing a substrate, the method comprising: transferring, by a transfer unit provided with a hand capable of supporting a substrate, the substrate to a liquid treating chamber to liquid-treat the substrate; unloading, by the hand, the substrate from the liquid treating chamber; and performing a weight measurement on the substrate unloaded from the liquid treating chamber using a weighting measuring unit installed in the transfer unit, wherein the weight measurement is performed in a state where the weight measuring unit disposed under the hand ascends to take over the substrate supported by the hand, and supports the substrate, and the substrate unloaded from the liquid treating chamber may be in a state in which a liquid film is formed on the substrate.

According to the exemplary embodiment of the present invention, wherein the weight measuring unit moves relative to the hand in a vertical direction to switch a position between a weight measurement position and a standby position, the weight measurement position is a position where the weight measuring unit ascends to support the substrate, and the standby position may be a position where the weight measuring unit descends to a position where it does not support the substrate.

According to the exemplary embodiment of the present invention, wherein when the weight measuring unit is at the weight measurement position, the hand may be positioned below the substrate while being spaced apart from the substrate.

According to the exemplary embodiment of the present invention, wherein the transfer unit further may performs a weight measurement on the substrate before loading the substrate into the liquid treating chamber.

According to the exemplary embodiment of the present invention, wherein a weight of a liquid remaining on the substrate may be calculated by comparing the weight of the substrate on which the liquid film is formed, which is unloaded from the liquid treating chamber, with the weight of the substrate before being loaded into the liquid treating chamber.

According to the exemplary embodiment of the present invention, wherein the substrate is liquid-treated in the liquid treating chamber and then transferred to the drying chamber to be dry-treated, the hand unloads the substrate from the drying chamber, and the weight measurement may be further performed on the substrate unloaded from the drying chamber by using the weight measuring unit installed in the transfer unit.

According to the exemplary embodiment of the present invention, wherein when the substrate is transferred to the liquid treating chamber, when the substrate is transferred from the liquid treating chamber to the drying chamber, and when the substrate is unloaded from the drying chamber, the substrate may be transferred using different hands.

An exemplary embodiment of the present disclosure, a substrate processing apparatus comprising: an index module including a load port and an index robot; and a treating module including a transfer frame including a buffer for temporarily storing a substrate, a liquid treating chamber for liquid-treating a substrate, a drying chamber for removing a liquid remaining on the substrate, and a transfer unit for transferring the substrates between the buffer, the liquid treating chamber, and the drying chamber; and a controller, wherein the transfer frame further includes a fan unit that generates descending airflow in a transfer region therein, the transfer unit includes: a base including a frame provided with an inner space; hands installed to be vertically spaced apart from each other on an upper portion of the base to advance and retract based on the base; a weight measuring unit installed in the inner space of the base and measuring the weight of the substrate; a lifting driver installed in the inner space of the base to move up and down the weight measuring unit; and an airflow blocking plate placed above the hand to minimize the descending airflow from reaching the substrate, the weight measuring unit includes: a support on which the substrate is placed; a weight measuring sensor for measuring the weight of the substrate placed on the support; and a measuring device base for supporting the weight measuring sensor, the support includes: a bottom plate; and a plurality of support protrusions protruding upward from the bottom plate and being in contact with a bottom surface of the substrate, the plurality of support protrusions is disposed to support the substrate at points spaced apart from each other, a distance between two support protrusions adjacent to each other among the plurality of support protrusions is smaller than a radius of the substrate, the frame includes a plurality of through holes formed on an upper surface of the frame, the plurality of through holes are respectively provided at points corresponding to the plurality of support protrusions when viewed from above, the controller controls the lifting driver to move up and down the weight measuring unit between a weight measurement position and a standby position, the weight measurement position is a position where the weight measuring unit ascends and the support protrusion supports the substrate; and the standby position is a position where the support protrusion may be disposed below the substrate supported by the hand.

According to the exemplary embodiment of the present invention, wherein the controller may be configured to control the weight measuring unit to measure the weight of the substrate when the transfer unit transfers the substrate, control the transfer unit to measure the weight of the substrate before the substrate is loaded into the liquid treating chamber, and measure the weight of the substrate after the substrate is unloaded from the liquid treating chamber, and wherein the weight measurement of the substrate is performed by taking over, by the weight measuring unit, the substrate supported by the hand while ascending from the standby position to the weight measurement position.

According to the exemplary embodiment of the present invention, it is possible to automate a process of measuring weight of a substrate.

Further, according to the exemplary embodiment of the present invention, it is possible to minimize errors in measuring weight of a substrate.

Further, according to the exemplary embodiment of the present invention, it is possible to increase throughput by measuring the weight of the substrate during a substrate transport process.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a substrate processing apparatus according to an exemplary embodiment of the present invention.

FIG. 2 is a perspective view illustrating a transfer unit according to an exemplary embodiment of the present invention.

FIG. 3 is a cross-sectional view schematically illustrating an inside of the transfer unit of FIG. 2.

FIG. 4 is a diagram illustrating a weight measuring unit of FIG. 3 in detail.

FIG. 5 is a top plan view schematically illustrating a hand and the weight measuring unit.

FIG. 6 is a side view illustrating an inside of the transfer unit of FIG. 2.

FIG. 7 is a diagram schematically illustrating an exemplary embodiment of a first process chamber of FIG. 1.

FIG. 8 is a diagram schematically illustrating an exemplary embodiment of a second process chamber of FIG. 1.

FIG. 9 is a flowchart illustrating a method of processing a substrate using the above-described substrate processing apparatus.

FIG. 10 is a flowchart illustrating a method of measuring a weight of a substrate in each transfer operation of FIG. 9.

FIGS. 11 and 12 are diagrams illustrating a shape of the transfer unit in a first transferring operation of FIG. 9.

FIG. 13 is a diagram illustrating a shape of the transfer unit in a second transferring operation of FIG. 9.

FIG. 14 is a diagram illustrating a shape of the transfer unit in a third transferring operation of FIG. 9.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on a process of liquid-treating a substrate W by supplying a liquid, such as a cleaning liquid, onto a substrate W as an example. However, the present exemplary embodiment is not limited to the cleaning process, and may be applied to various processes of processing the substrate W using a liquid, such as an etching process, an ashing process, or a developing process.

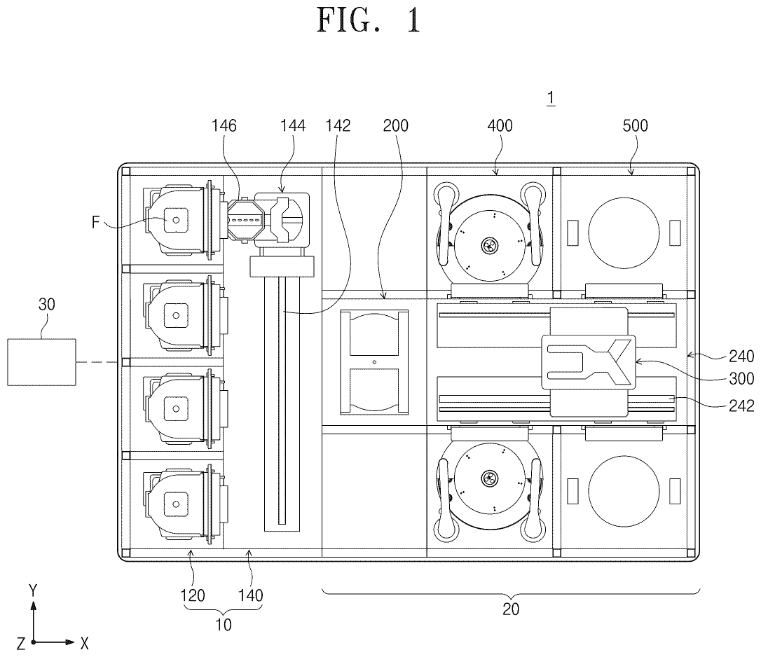

Hereinafter, an exemplary embodiment of the present invention will be described with reference to FIGS. 1 to 14. A substrate processing apparatus 1 according to an exemplary embodiment of the present invention may perform a cleaning process including a drying process of drying a substrate W using a process fluid.

FIG. 1 is a top plan view schematically illustrating a substrate processing apparatus according to an exemplary embodiment of the present invention, Referring to FIG. 1, a substrate processing apparatus 1 includes an index module 10, a treating module 20, and a controller 30. According to an example, the index module 10 and the treating module 20 are disposed along one direction. Hereinafter, a direction in which the index module 10 and the treating module 20 are arranged is defined as a first direction X. When viewed from above, a direction perpendicular to the first direction X is defined as a second direction Y, and a direction perpendicular to a plane including both the first direction X and the second direction Y is defined as a third direction Z.

The index module 10 transfers a substrate W from a container F in which the substrate W is accommodated to the treating module 20 processing the substrate W. The index module 10 accommodates the substrate W completely processed in the treating module 20 in the container F. A longitudinal direction of the index module 10 is provided in the second direction Y. The index module 10 includes a load port 120 and an index frame 140.

The container F in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction Y. The number of load ports 120 may increase or decrease according to the process efficiency and footprint conditions of the treating module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction Y in its longitudinal direction. The index robot 144 may transfer the substrate W. The index robot 144 may transfer the substrate W between the index module 10 and a buffer chamber 200 to be described later.

The index robot 144 includes an index hand 146. The substrate W is seated on the index hand 146. The index hand 146 may be provided on the index rail 142 to be movable along the second direction Y. Accordingly, the index hand 146 may be moved forward and backward along the index rail 142. Also, the index hand 146 may be provided to be rotatable with respect to the third direction Z. Also, the index hand 146 may be provided to be vertically movable along the third direction Z. A plurality of index hands 146 may be provided. A plurality of index hands 146 may be provided to be spaced apart from each other in the vertical direction. A plurality of index hands 146 may move forward, backward, and rotate independently of each other.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform a substrate processing method described below. For example, the controller 30 may control the configurations provided to the transfer unit 300 and the process chambers 400 and 500 so as to perform a substrate processing method described below.

The treating module 20 includes a buffer chamber 200, a transfer frame 240, and process chambers 400 and 500. The buffer chamber 200 provides a space in which the substrate W loaded into the treating module 20 and the substrate W unloaded from the treating module 20 stay temporarily. The transfer frame 240 provides a transfer space for transferring the substrate W between the buffer chamber 200 and the process chambers 400 and 500. The transfer frame 240 may be provided with a fan unit 246 that generates descending airflow in the transfer region therein.

The buffer chamber 200 is disposed between the index frame 140 and the transfer frame 240. The buffer chamber 200 may be located at one end of the transfer frame 240.

The buffer chamber 200 provides a space in which the substrate W stays before the substrate W is transferred between the index robot 144 and the transfer unit 300.

A slot (not illustrated) in which the substrate W is placed is provided in the buffer chamber 200. A plurality of slots (not illustrated) is provided. A plurality of slots (not illustrated) may be disposed to be spaced apart from each other along the third direction Z. The index robot 144 may withdraw the substrate W from the container F and place the substrate W in the slot of the buffer chamber 200. The transfer unit 300 of the transfer frame 240 may withdraw the substrate W placed in the slot of the buffer chamber 200 and transfer the substrate W to the first process chamber 400 or the second process chamber 500.

A front face of the buffer chamber 200 is a face facing the index module 10, and a rear face of the buffer chamber 200 is a face facing the transfer frame 240. The index robot 144 may approach the buffer chamber 200 through the front face, and the transfer robot 300 may approach the buffer chamber 200 through the rear face.

A longitudinal direction of the transfer frame 240 may be provided along the first direction X. The process chambers 400 and 500 may be disposed on opposite sides of the transfer frame 240. The process chambers 400 and 500 may be disposed on a side portion of the transfer frame 240. The transfer frame 240 and the process chambers 400 and 500 may be disposed along the second direction Y. According to the example, the process chambers 400 and 500 are disposed on opposite sides of the transfer frame 240. At one side of the transfer frame 240, the process chambers 400 and 500 may be provided in an array of A ×B (each of A and B is 1 or a natural number larger than 1) in the first direction X and the third direction Z. Herein, A is the number of process chambers 400 and 500 provided in a row along the first direction X, and B is the number of process chambers 400 and 500 provided in a row along the third direction Z. For example, when four process chambers 400 and 500 are provided at one side of the transfer frame 240, the process chambers 400 may be arranged in a 2×2 array. The number of process chambers 400 and 500 may increase or decrease. Unlike the above description, the process chambers 400 and 500 may be provided as a single layer on one side and opposite sides of the transfer frame 240.

The transfer frame 300 includes a guide rail 242 and a transfer unit 300. The guide rail 242 is provided within the transfer frame 240 in the first direction X in a longitudinal direction thereof. The transfer unit 300 may be provided on the guide rail 242 to be able to move linearly along the first direction X. Also, the transfer unit 300 may be provided to be rotatable with respect to the third direction Z. Also, the transfer unit 300 may be provided to be vertically movable along the third direction Z. The transfer robot 300 transfers the substrate W between the buffer chamber 200 and the process chambers 400 and 500.

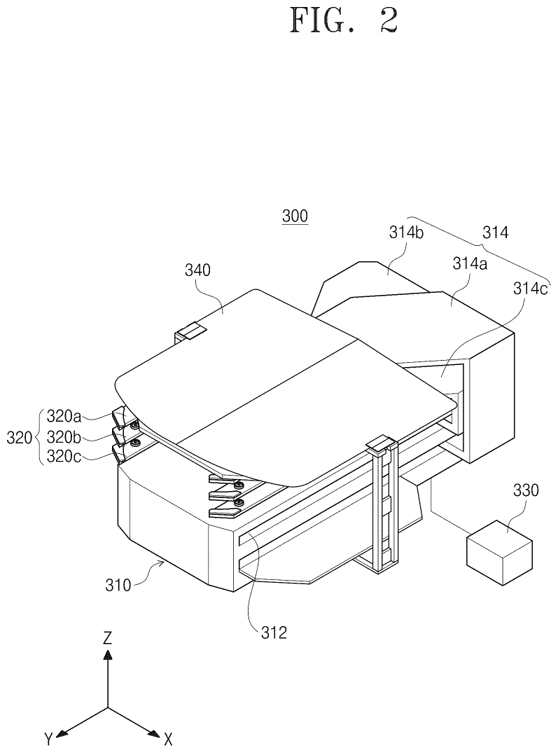

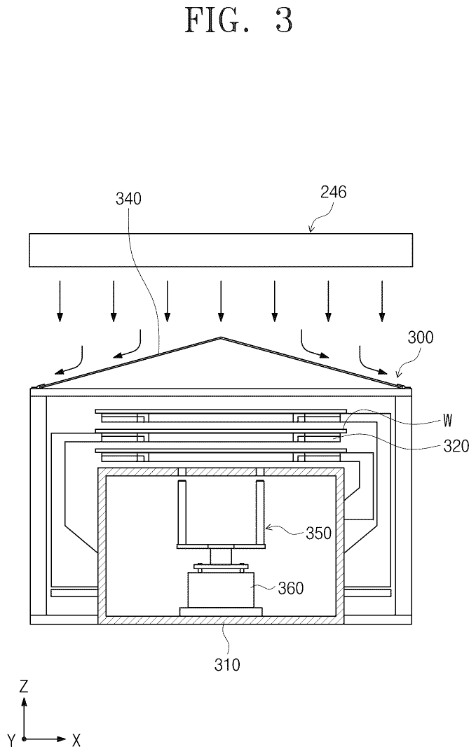

FIG. 2 is a perspective view illustrating the transfer unit according to the exemplary embodiment of the present invention, and FIG. 3 is a cross-view sectional schematically illustrating the inside of the transfer unit of FIG. 2 when viewed from the front. Referring further to FIGS. 2 and 3 in FIG. 1, the transfer unit 300 includes a base 310, an arm 314, a hand 320, a driving unit 330, an airflow blocking plate 340, a weight measuring unit 350, and a lifting driving unit 360.

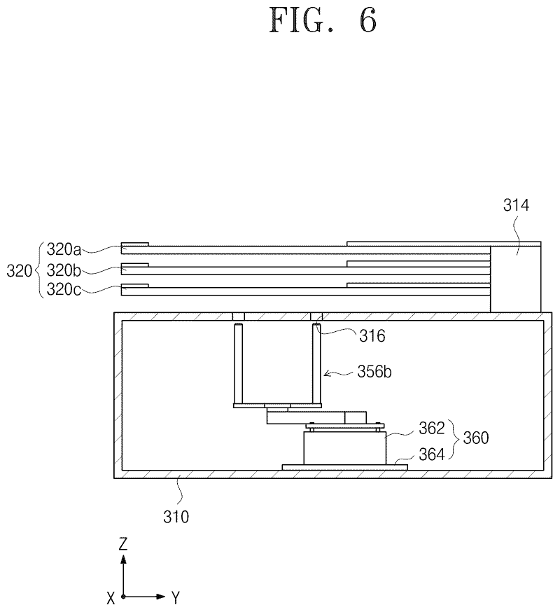

The base 310 is installed to be movable along the guide rail 302. The base 310 supports the arm 314 and the hand 320 connected to the arm 314. The arm 314 is connected with the base 310. An end of the arm 314 is connected to the hand 320. The base 310 may be axially rotated with respect to a support shaft (not illustrated) in the third direction Z. The base 310 may have a generally rectangular parallelepiped shape. The base 310 is provided such that a longitudinal direction thereof is directed in a horizontal direction. A guide 312 is provided on the base 310. The guide 312 guides the movement direction of the arm 314 so that the arm 314 and the hand 320 coupled to the arm 314 may move linearly along the longitudinal direction of the base 310, that is, the second direction Y of FIG. 6. A plurality of guides 312 may be provided. The arm 314 is provided to be able to advance and retract relative to the base 310 by the driving unit 330. When the arm 314 advances relative to the base 310, the hand 320 may be placed in an advance position, and when the arm 314 retracts relative to the base 310, the hand 320 may be placed in a retract position. When the hand 320 is placed in the retract position, the hand 320 may be located above the base 310.

The base 310 may have a rectangular parallelepiped shape including a frame (not illustrated) in which the inner space is provided. A driving unit, such as a guide rail and a motor, capable of driving the arm 314 may be disposed in the inner space of the base 310. The weight measuring unit 350 and the lifting driving unit 360 are installed in the inner space of the base 310.

According to an example, the same number of guides 312 as the number of arms 314 may be provided. Each of the guides 312 may be provided such that a longitudinal direction thereof is parallel to the base 310.

The arm 314 and the hand 320 coupled to the arm 314 may be stacked above the base 310 to be spaced apart from each other in the vertical direction, that is, the third direction Z, and may be provided in plural. A plurality of arms 314 may be linearly driven independently of each other by the driving unit 330. Accordingly, the plurality of transfer hands 320 is capable of moving forward and backward, and rotating independently of each other by the driving unit 330.

In the following exemplary embodiment, the present invention will be described based on the illustration that the transfer unit 300 includes three arms 314a, 314b, and 314c in which one hand 320 is coupled, that is, the transfer unit 300 includes a first hand 320a, a second hand 320b, and a third hand 320c, but unlike this, the number of arms 314 and the hands 320 may be freely changed according to the process efficiency of the substrate processing apparatus 1.

The substrate W is placed on the hand 320. The hand 320 directly loads or unloads the substrate W into or from the process chambers 400 and 500 through an entrance. The plurality of hands 320 may be provided to transfer the substrates W in different states. For example, some of the plurality of hands 320 may be provided to transfer the substrate W before being loaded into the process chambers 400 and 500, and others may be provided to transfer the process-completed substrate W in the process chambers 400 and 500. This will be described later.

The airflow blocking plate 340 blocks the descending airflow formed in the transfer frame 240 by the fan unit 246 from reaching the substrate W placed on the hand 320. In addition, when the weight measuring unit 350 described later measures the weight of the substrate W placed on the hand 320, the airflow blocking plate 340 blocks the descending airflow from reaching the substrate W. The airflow blocking plate 340 blocks the arrival of the descending airflow onto the substrate W in the weight measuring process of the substrate W described later, thereby minimizing a weight measuring error.

The airflow blocking plate 340 is fixedly coupled to the base 310 so as to be disposed above the hand 320. The airflow blocking plate 340 is disposed at a position higher than an upper end of the substrate entrances of the process chambers 400 and 500 when the hand 320 loads or unloads the substrate W to or from the process chambers 400 and 500. The airflow blocking plate 340 is provided with an area larger than the substrate W when viewed from above.

The airflow blocking plate 340 is obliquely provided such that the height of the airflow blocking plate 340 decreases toward opposite sides from the center thereof. Accordingly, the descending airflow may flow outside the region of the hand 320 provided with the substrate W along an inclined surface of the airflow blocking plate 340. When viewed from the top, the airflow blocking plate 340 may be provided such that one side surfaces of two plates are fixedly coupled to each other in the central region of the hand 320. Each of the plates may be obliquely provided downward from the central region to the edge region of the hand 320.

The weight measuring unit 350 measures a weight of the substrate W. The weight measuring unit 350 may be installed under the hand 320 of the transfer unit 300. The weight measuring unit 350 may be disposed under the hand 320 when the hand 320 is in the retracted position. For example, the weight measuring unit 350 may be installed in an inner space of a frame (not illustrated) of the base 310. The weight measuring unit 350 is installed on the lifting driving unit 360 and moves relative to the hand 320 in the vertical direction, so that the weight measuring unit 350 may move between a weight measurement position for measuring the weight of the substrate W and a standby position for which the weight measuring unit 350 does not measure the weight of the substrate W.

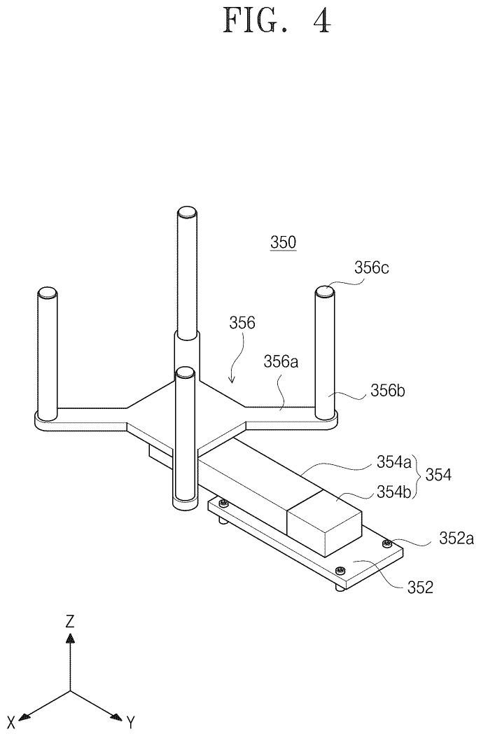

FIG. 4 is a diagram illustrating the weight measuring unit of FIG. 3 in detail. Hereinafter, the weight measuring unit 350 of the present invention will be described in detail with reference to FIG. 4.

The weight measuring unit 350 measures a weight of the substrate W. The weight measuring unit 350 includes a measuring device base 352, a weight measuring sensor 354, and a support 356.

The measuring device base 352 is installed on the upper portion of the lifting driving unit 360. The measuring device base 352 may be provided as a flat plate. The measuring device base 352 may be installed in the upper portion of the lifting driving unit 360 to be fixed in the first direction X and the second direction Y. The measuring instrument base 352 may further include a horizontal adjustment member 352a.

The horizontal adjustment member 352a adjusts the horizontality of the measuring device base 352, and may adjust the degree of horizontality of the substrate W placed on the support 356 by adjusting the horizontality of the support 356. The horizontal adjustment member 352a may be installed at a corner of the measuring device base 352. The horizontality adjustment member 352a may be provided as, for example, a headless bolt, to adjust the height of each corner of the measuring device base 352 in the third direction Z.

The weight measuring sensor 354 measures the weight of the substrate W seated on the support 356. The weight measuring sensor 354 is fixedly installed on the measuring device base 352. The weight measuring sensor 354 may include, for example, a load cell 354a for measuring strain through a strain gauge, and an indicator 354b for transmitting the value measured by the load cell 354a to the controller 30. The weight measuring sensor 354 transmits the measured weight information to the controller 30. The weight measuring sensor 354 may be provided on the measuring instrument base 352 in a cantilever shape. One end of the weight measuring sensor 354 may be fixedly installed on the measuring device base 352, and the other end of the weight measuring sensor 354 may be configured as a free end, and the support 356 may be installed thereon. When the substrate W is seated on the support 356, the support 356 and the other end of the weight measuring sensor 354 are deformed according to the weight of the substrate W, and the weight of the substrate W may be measured using the strain at which the weight measuring sensor 354 is deformed.

The support 356 may support the substrate W. The support 356 includes a bottom plate 356a and a support protrusion 356b. The bottom plate 356a is installed on the weight measuring sensor 354. The bottom plate 356a may be installed on the end of the weight measuring sensor 354. The end of the weight measuring sensor 354 in which the bottom plate 356a is installed may be provided as a free end.

The support protrusion 356b protrudes upward from the bottom plate 356a, and is in contact with the bottom surface of the substrate W placed on the support 356. The support protrusion 356b is provided flat to support the bottom surface of the substrate W. A guide 356c made of a material having a high coefficient of friction so as to support the substrate W and prevent the substrate W from slipping may be further provided on an upper end of the support protrusion 356b.

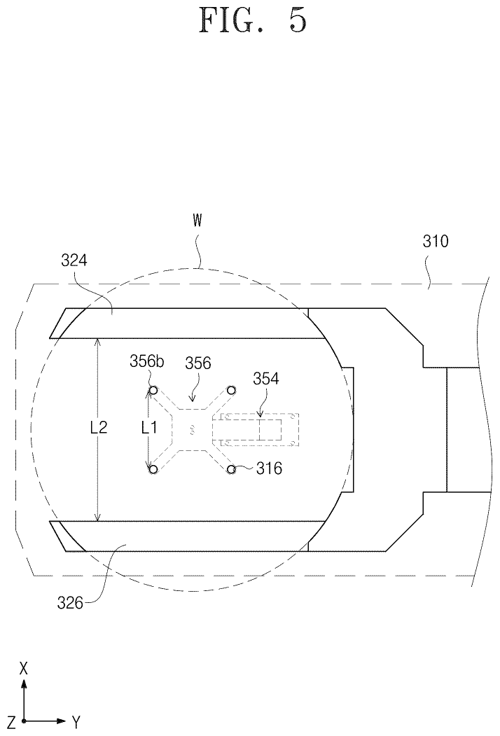

A plurality of support protrusions is are provided. A plurality of support protrusions 356b may be disposed to support the bottom surface of the substrate W at points spaced apart from each other. A plurality of support protrusions 356b may be disposed at positions at which warpage due to the weight of the substrate W may be minimized when supporting the bottom surface of the substrate W. For example, four support protrusions 356b may be provided and disposed to support the substrate W by four points. The support protrusions 356b may be disposed to surround the virtual center when viewed from above. FIG. 5 is a top plan view schematically illustrating the hand and the weight measuring unit. Referring to FIG. 5, a distance L1 between two adjacent support protrusions 356b among the plurality of support protrusions 356b may be provided to be smaller than a radius of the substrate W.

The hand 320 may include a pair of fingers 324 and 326 capable of supporting the bottom surface of the substrate W. The pair of fingers 324 and 326 may be provided in the shape of a rod extending in one direction to support the bottom surface of the substrate W.

The pair of fingers 324 and 326 and the support protrusion 356b may be configured and disposed so as not to interfere with each other when the support protrusion 356b moves upward and downward between the weight measurement position and the standby position to be described below. The hand 320 and the support protrusion 356b may be disposed so that the substrate W is capable of being transferred between the hand 320 and the support protrusion 356b as the hand 320 ascends and descends. In other words, the support protrusion 356b may be disposed so that the hand 320 and the support protrusion 356b do not interfere with the substrate W in a series of process in which the support protrusion 356b ascends from the standby position to the weight measurement position to take over the substrate W from the hand 320 or the support protrusion 356b descends from the weight measurement position to the standby position to hand over the substrate W to the hand 320.

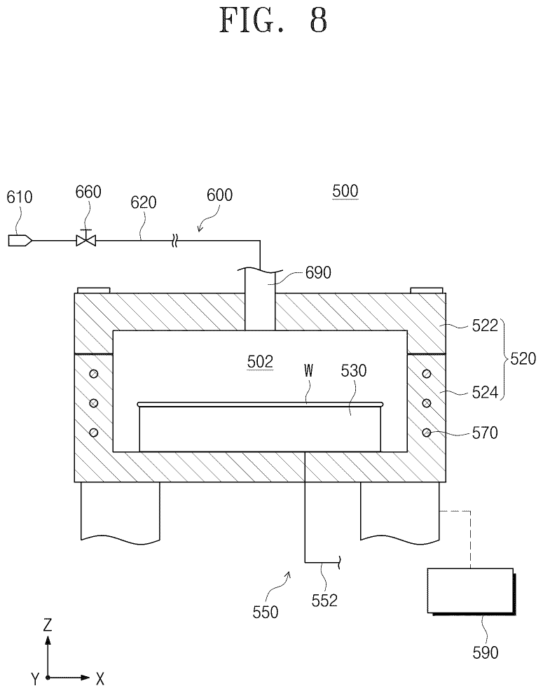

For example, as illustrated in FIG. 8, a distance L2 between the pair of fingers 324 and 326 is greater than the distance L1 between the two adjacent support protrusions 356b, so that the hand 320 and the support protrusions 356b may be disposed so as not to overlap when viewed from above.

The lifting driving unit 360 may move upward and downward the weight measuring unit 350. The lifting driving unit 360 may move the weight measuring unit 350 relative to the hand 320 in the third direction Z that is the vertical direction.

FIG. 6 is a side view illustrating an inside of the transfer unit of FIG. 2. Referring further to FIG. 6, the lifting driving unit 360 includes a shaft 362 and a lifting driver 364. The lifting driver 364 may move up and down the shaft 362. The lifting driver 364 may be a motor. However, the present invention is not limited thereto, and the lifting driver 364 may be provided as a well-known driver, such as a cylinder.

The weight measuring unit 350 is installed on the shaft 362. The measuring device base 352 may be installed on the upper end of the shaft 362. The lifting driver 364 may raise the weight measuring unit 350 by moving up and down the shaft 362. As the lifting driver 364 raises the weight measuring unit 350, the support protrusion 356b of the weight measuring unit 350 may ascend from the lower portion of the hand 320 and may be in contact with the substrate W supported by the hand 320.

As the lifting driver 364 raises the weight measuring unit 350, the support protrusion 356b may be in contact with the bottom surface of the substrate W placed on the hand 320, and the support protrusion 356b may further ascend to take over the substrate W from the hand 320 and support the substrate W. The weight measuring unit 350 may measure the weight of the substrate W in a state in which the support protrusion 356b takes over the substrate W from the hand 320 and supports the substrate W. When the weight is measured in the state where the support protrusion 356b supports the substrate W, the positions of the support protrusion 356b and the weight measuring unit 350 may be defined as weight measurement positions. When the weight measuring unit 350 is in the weight measurement position, the hand 320 is spaced apart from the substrate W without supporting the substrate W. When the weight measuring unit 350 is in the weight measurement position, the hand 320 may be positioned under the substrate W while being spaced apart from the substrate W.

The lifting driver 364 may lower the weight measuring unit 350 after the weight measuring unit 350 measures the weight of the substrate W. As the lifting driver 364 lowers the weight measuring unit 350, the substrate W supported by the support protrusion 356b may be handed over to the hand 320, and the support protrusion 356b may further descend and be disposed below the hand 320 and the substrate supported by the hand 320. A position where the support protrusion 356b of the weight measuring unit 350 does not support the substrate W, i.e., a position of the support protrusion 356b and the weight measuring unit 350 when the support protrusion 356b is disposed below the substrate W supported by the hand 320, may be defined as a standby position.

In order to prevent the support protrusion 356b of the weight measuring unit 350 from interfering with the frame (not illustrated) of the base 310 when the support protrusion 356b of the weight measuring unit 350 ascends and descends to move between the weight measurement position and the standby position, a through hole 316 may be formed in the upper surface of the frame of the base 310. A plurality of through holes 316 may be provided. As illustrated in FIG. 6, a plurality of through holes 316 may be provided at points corresponding to the support protrusion 356b when viewed from above.

Referring back to FIG. 1, the process chambers 400 and 500 may process the substrate W. The process chambers 400 and 500 may include a first process chamber 400 and a second process chamber 500. For example, the first process chamber 400 and the second process chamber 500 may be sequentially disposed on opposite sides of the transfer frame 300, respectively, in the first direction X. On the contrary, the first process chambers 400 may be disposed on one side of the transfer frame 240 in the first direction X, and the second process chambers 500 may be disposed on the other side of the transfer frame 240 in the first direction X.

The first process chamber 400 and the second process chamber 500 may be provided to sequentially perform a process on one substrate W. The first process chamber 400 may be provided as a liquid treating chamber for liquid-treating a substrate, and the second process chamber 500 may be provided as a drying chamber for removing a liquid remaining on the substrate. For example, a chemical process, a rinsing process, and a substitution process may be performed on the substrate W in the first process chamber 400, and a drying process may be performed on the substrate W in the second process chamber 500. In this case, the substitution process may be performed by an organic solvent, and the drying process may be performed by a supercritical fluid. An isopropyl alcohol (IPA) liquid may be used as the organic solvent, and carbon dioxide (CO2) may be used as the supercritical fluid.

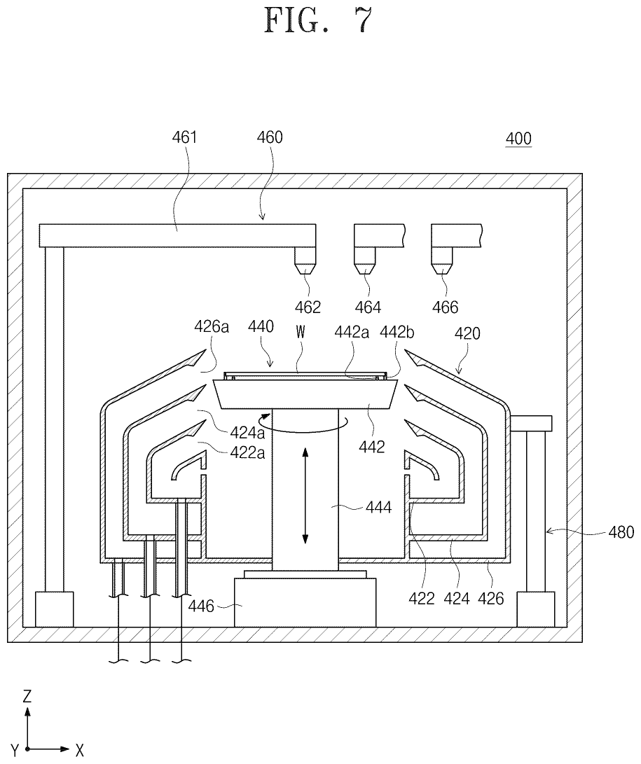

FIG. 7 is a diagram schematically illustrating an exemplary embodiment of the first process chamber of FIG. 1. Referring to FIG. 7, the first process chamber 400 may include a housing 410, a cup 420, a support unit 440, a liquid supply unit 460, and a lifting unit 480.

The housing 410 is provided in a generally rectangular parallelepiped shape. The cup 420, the support unit 440, and the liquid supply unit 460 may be disposed within the housing 410.

The cup 420 has a treatment space with an open top, and the substrate W is liquid-treated in the treatment space. The support unit 440 supports the substrate W in the treatment space. The liquid supply unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to an example, the cup 420 may include a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid processing process proceeds, the processing liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a drive shaft 444. An upper surface of the support plate 442 may be provided in a generally circular shape, and may have a diameter larger than a diameter of the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge portion of the support plate 442. The chuck pin 442b is provided to protrude upward from the support plate 442, and supports the side portion of the substrate W so that the substrate W does not deviate from the support unit 440 when the substrate W is rotated. The drive shaft 444 is driven by a driver 446, is connected to the center of the bottom surface of the substrate W, and rotates the support plate 442 about its central axis.

According to an example, the liquid supply unit 460 may include a first nozzle 462, a second nozzle 464, and a third nozzle 466. The first nozzle 462 may supply the first liquid onto the substrate W. The first liquid may be a liquid for removing a film or foreign substances remaining on the substrate W. The second nozzle 464 may supply the second liquid onto the substrate W. The second liquid may be a liquid that is well soluble in a third liquid. For example, the second liquid may be a liquid that is more easily soluble in the third liquid than in the first liquid. The second liquid may be a liquid that neutralizes the first liquid supplied onto the substrate W. Also, the second liquid may be a liquid that neutralizes the first liquid and is soluble better in the third liquid compared to the first liquid. According to an example, the second liquid may be pure water (DIW). The third nozzle 466 may supply the third liquid onto the substrate W. The third liquid may be a liquid that is well soluble in a supercritical fluid used in the second process chamber 500. According to an example, the third liquid may be a volatile organic solvent, pure water, or a mixture of pure water and a surfactant. The third liquid may be an organic solvent. The organic solvent may be isopropyl alcohol (IPA). According to an example, the supercritical fluid may be carbon dioxide. The substrate may be unloaded from the first process chamber 400 in a state in which the third liquid is applied and loaded into the second process chamber 500.

The first nozzle 462, the second nozzle 464, and the third nozzle 466 are supported by different arms 461, and these arms 461 may be moved independently. Selectively, the first nozzle 462, the second nozzle 464, and the third nozzle 466 may be mounted on the same arm 461 and simultaneously moved.

The lifting unit 480 moves the cup 420 in the vertical direction. By the vertical movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 may be fixedly installed, and the lifting unit 480 may move the support unit 440 in the vertical direction.

FIG. 8 is a diagram schematically illustrating an exemplary embodiment of the second process chamber of FIG. 1.

According to the exemplary embodiment, the second process chamber 500 removes a liquid on the substrate W by using a supercritical fluid. The second process chamber 500 may include a body 520, a substrate support body 530, and a fluid supply unit 600.

The body 520 may provide a treatment space 502 in which a cleaning process is performed. The body 520 may have an upper body 522 and a lower body 524 and the upper body 522 and the lower body 524 may be combined to provide the above-described treatment space 502. The upper body 522 is provided at the upper portion of the lower body 524. The upper body 522 may be fixed in position, and the lower body 524 may be raised and lowered by a driving member 590, such as a cylinder. When the lower body 524 is spaced apart from the upper body 522, the treatment space 502 is opened, and in this case, the substrate W is loaded and unloaded. During the drying process, the lower body 524 is in close contact with the upper body 522 so that the treatment space 502 is sealed from the outside.

The second process chamber 500 may include a heater 570. According to an example, the heater 570 may be located inside a wall of the body 520. The heater 570 may heat the treatment space 502 of the body 520 so that the fluid supplied into the inner space of the body 520 maintains a supercritical state. An atmosphere by the supercritical fluid is formed inside the treatment space 502.

The substrate support body 530 supports the substrate W in the treatment space 502 of the body 520.

The fluid supply unit 600 supplies a cleaning fluid to the treatment space 502 of the body 520. According to an example, the cleaning fluid may be supplied to the treatment space 502 in a supercritical state. In contrast, the cleaning fluid may be supplied to the treatment space 502 in a gaseous state and may be phase-changed to a supercritical state within the treatment space 502.

According to an example, the fluid supply unit 600 includes a fluid supply port 690, a supply line 620, and a valve 660. The fluid supply port 690 directly supplies the supercritical fluid to the upper surface of the substrate W. The fluid supply port 690 is provided by being connected to the upper body 522. The fluid supply unit 600 may further include a lower fluid supply port (not illustrated) connected to the lower body 524. The supercritical fluid injected from the fluid supply port 690 reaches the central region of the substrate W and spreads to the edge region, thereby being uniformly provided to the entire region of the substrate W. The supply line 620 is connected to the fluid supply port 690. The supply line 620 receives the supercritical fluid from an outside separate supercritical fluid storage unit 610, and supplies the supercritical fluid to the fluid supply port 690. For example, the supercritical fluid storage unit 610 may store a supercritical fluid, which may be carbon dioxide or the like, and supply the supercritical fluid to the supply line 620.

The valve 660 is installed in the supply line 620. The valve 660 adjusts the flow rate of the supercritical fluid supplied to the fluid supply port 690. The valve 660 may adjust the flow rate supplied into the treatment space 502 by a controller (not illustrated).

The exhaust member 550 exhausts the supercritical fluid from the second process chamber 500. The exhaust member 550 may be connected to an exhaust line 552 that exhausts the supercritical fluid. In this case, a valve (not illustrated) may be installed in the exhaust member 550 to adjust the flow rate of the supercritical fluid exhausted to the exhaust line 552. The supercritical fluid exhausted through the exhaust line 552 may be released into the air or may be supplied to a supercritical fluid regeneration system (not illustrated). The exhaust member 550 may be coupled to the lower body 524.

Hereinafter, an exemplary embodiment of a method of processing a substrate using the substrate processing apparatus of FIG. 1 will be described. The substrate processing method described below may be performed by the substrate processing apparatus 1 including the index module 10, the first process chamber 400, the second process chamber 500, and the transfer unit 300. In addition, the controller 30 may control the configurations of the substrate processing apparatus 1 to perform the substrate processing method described below.

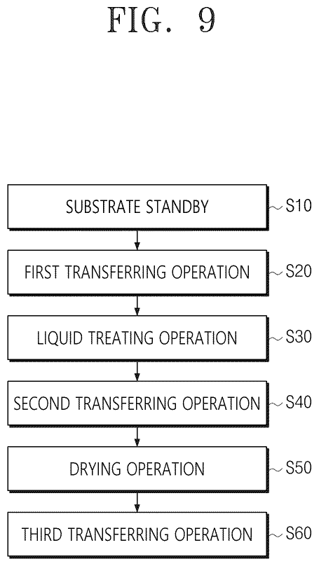

FIG. 9 is a flowchart illustrating a method of processing a substrate using the above-described substrate processing apparatus.

Referring to FIG. 9, the substrate processing method of the present invention includes a substrate standby operation S10, a first transferring operation S20, a liquid treating operation S30, a second transferring operation S40, a drying operation S50, and a third transferring operation S60. The above-described substrate standby operation S10 to third transferring operation S60 may be sequentially performed.

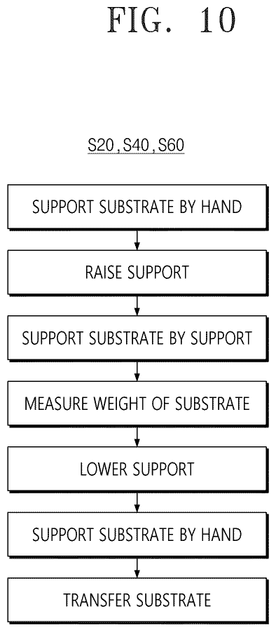

FIG. 10 is a flowchart illustrating a method of measuring a weight of a substrate in each transferring operation of FIG. 9. In describing the method of measuring the weight of the substrate W in each transferring operation S20, S40, and S60 with further reference to FIG. 10, in a state in which the hand 320 supports the substrate W, as the weight measuring unit 350 is raised by the lifting driving unit 360, the support 356 and the support protrusion 356b may ascend, the support protrusion 356b of the support 356 may take over the substrate W from the hand 320 to support the bottom surface of the substrate W, and the weight measuring sensor 354 may measure the weight of the substrate W.

When the weight measurement on the substrate W is completed while the weight measurement on the substrate W is performed, the weight measuring unit 350 is lowered by the lifting driving unit 360, and the hand 320 takes over the substrate W from the support 356 again and supports the substrate W, and the transfer unit 300 transfers the substrate W.

The substrate standby operation S10 will be described with reference to FIG. 9 again. In the substrate standby operation S10, the substrate W is loaded into the buffer chamber 200. The index robot 144 may transfer the substrate W from the load port 120 of the index module 10 to the buffer chamber 200. The substrate W loaded into the buffer chamber 200 may be supported by a slot (not illustrated).

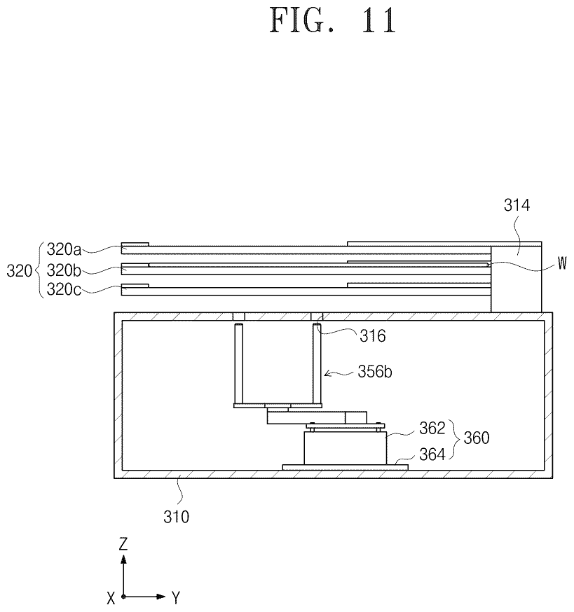

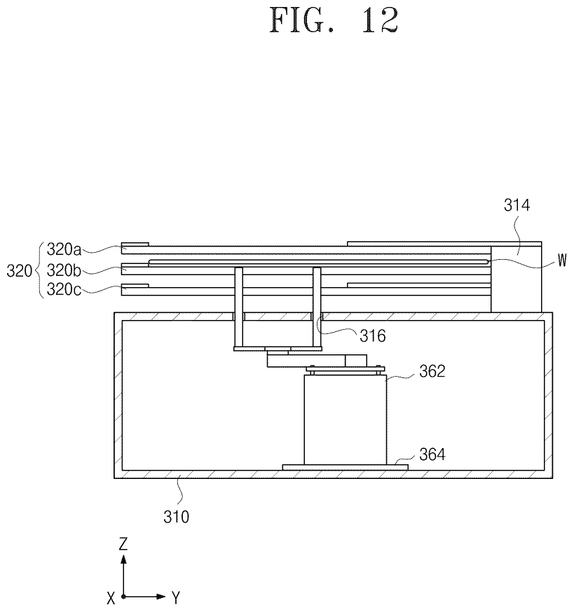

When the substrate W is loaded into the buffer chamber 200, a first transferring operation S20 is performed. FIGS. 11 and 12 are diagrams illustrating a shape of the transfer unit in the first transferring operation of FIG. 9. Referring further to FIGS. 11 to 12, in the first transferring operation S20, the transfer unit 300 may transfer the substrate W to the first process chamber 400. The hand 320 of the transfer unit 300 withdraws the substrate W from the buffer chamber 200 and transfers the substrate W to the first process chamber 400. In the first transferring operation S20, the substrate W may be transferred by using a specific hand 320 among a plurality of hands 320a, 320b, and 320c provided to the transfer unit 300. For example, in the exemplary embodiment of the present invention, the substrate W may be transferred by using the second hand 320b in the first transferring operation S20.

As illustrated in FIG. 12, while the transfer unit 300 transfers the substrate W from the buffer chamber 200 to the first process chamber 400 in the first transferring operation S20, the weight measurement on the substrate W placed on the hand 320 is performed. The weight measurement may be performed as described with reference to FIG. 10.

After the first transferring operation S20 is performed to measure the weight of the substrate W, and the substrate W is transferred to the first process chamber 400, and then a liquid treating operation S30 is performed. In the liquid treating operation S30, the first process chamber 400 may perform the liquid treatment on the transferred substrate W. The transfer unit 300 may unload the substrate W, on which the liquid treatment has been completed, from the first process chamber 400. A liquid may be applied on the substrate W, which has been unloaded from the first process chamber 400 after the liquid treatment has been completed. For example, a third liquid may remain on the substrate W, which has been unloaded from the first process chamber 400 after the liquid treatment has been completed.

After the liquid treating operation S30, a second transferring operation S40 is performed. In the second transferring operation S40, the transfer unit 300 may transfer the substrate W from the first process chamber 400 to the second process chamber 500. The hand 320 of the transfer unit 300 withdraws the substrate W from the first process chamber 400 and transfers the substrate W to the second process chamber 500. In the second transferring operation S40, the substrate W may be transferred by using a specific hand 320 among the plurality of hands 320a, 320b, and 320c provided to the transfer unit 300. The hand 320 transferring the substrate W in the second transferring operation S40 may be different from the hand 320 transferring the substrate W in the first transferring operation S20 described above. For example, in the exemplary embodiment of the present invention, the substrate W may be transferred by using the third hand 320c in the second transferring operation S40. The third hand 320c may be a hand disposed at the lowermost side among the plurality of hands 320. Since the substrate W transferred in the second transferring operation S40 is the substrate W in which the liquid is applied to form the liquid film C, the liquid on the substrate W may fall or scatter during the transferring process of the substrate W to contaminate the transfer unit 300. When the second transferring operation S40 is performed using the hand 320c disposed at the lowermost portion among the plurality of hands 320, it is possible to prevent the liquid on the substrate W from falling and contaminating the other hands 320a and 320b during the transferring process of the substrate W.

While the transfer unit 300 transfers the substrate W from the first process chamber 400 to the second process chamber 500 in the second transferring operation S40, the weight of the substrate W placed on the hand 320 is measured. The weight of the substrate W measured in the second transferring operation S40 is the weight of the substrate W in a state in which the liquid is applied to form the liquid film C.

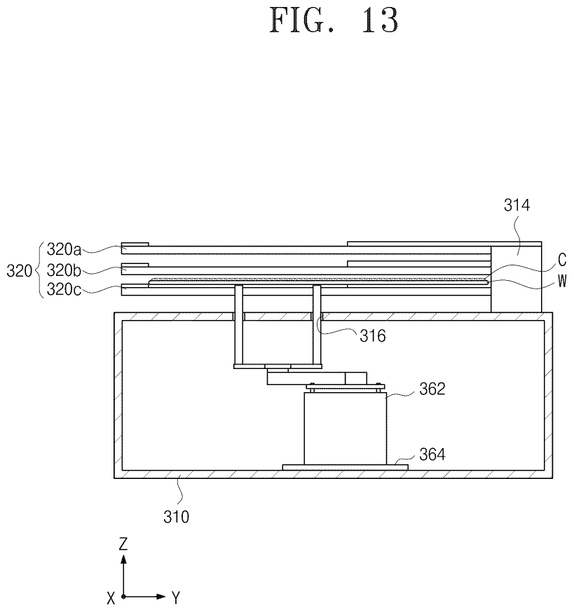

The weight measurement method is the same as that described above with reference to FIG. 10, and may be performed in the same manner as in the first transferring operation S20. FIG. 13 is a diagram illustrating a shape of the transfer unit in the second transferring operation of FIG. 9.

Referring to FIG. 13, compared to FIG. 12 in which the weight of the substrate W is measured in the first transferring operation S20, there is a difference in that the liquid film C is formed on the substrate W. Also, unlike the first transferring operation S20 in which the substrate W is supported and transferred by the second hand 320b, the substrate W is supported and transferred by the third hand 320c in the second transferring operation S40 of the present exemplary embodiment. Accordingly, the distance at which the support protrusion 356b of the weight measuring unit 350 is required to be raised to support the substrate W may be different in the first transferring operation S20 and the second transferring operation S40.

The controller 30 may derive the weight of the liquid applied on the substrate W by calculating the difference between the weight of the substrate W measured by the weight measuring sensor 254 in the second transferring operation S40 and the weight of the substrate W measured by the weight measuring sensor 254 in the first transferring operation S20.

The controller 30 may measure the weight of the substrate W on which the liquid film C is formed immediately after the substrate W is unloaded from the first process chamber 400 or immediately before the substrate W is inserted into the second process chamber 500 by adjusting the time point at which the weight of the substrate W is measured in the second transferring operation S40. For example, when the weight of the substrate W is measured immediately after the substrate W is unloaded from the first process chamber 400, the amount of the liquid volatilized in the transferring process of the substrate W may be minimized, and thus the weight of the liquid remaining on the substrate W immediately after the liquid treating operation S30 is performed may be accurately measured. For example, when the weight of the substrate W is measured immediately before the substrate W is inserted into the second process chamber 500, even if the liquid is partially volatilized in the transfer process of the substrate W, the weight of the substrate W is measured immediately before the drying operation S50 is performed, the weight of the liquid on the substrate W requiring drying may be accurately measured. Accordingly, according to the exemplary embodiment of the present invention, the weight of the liquid remaining on the substrate W at a specific time point may be derived.

The second transferring operation S40 is performed to measure the weight of the substrate W, the substrate W is transferred to the second process chamber 500, and then the drying operation S50 is performed. In the drying operation S50, the second process chamber 500 may dry-treat the transferred substrate W. The second process chamber 500 may dry-treat the substrate W to remove the liquid film C on the substrate W. The transfer unit 300 may unload the substrate W, which has been dried, from the second process chamber 500.

A third transferring operation S60 is performed after the drying operation S50. In the third transferring operation S60, the transfer unit 300 may transfer the substrate W from the second process chamber 500 to the buffer chamber 200. The hand 320 of the transfer unit 300 unloads the substrate W from the second process chamber 500 and transfers the substrate W to the buffer chamber 200. In the third transferring operation S60, the substrate W may be transferred by using a specific hand 320 among the plurality of hands 320a, 320b, and 320c provided to the transfer unit 300. The hand 320 transferring the substrate W in the third transferring operation S60 may be different from the hand 320 transferring the substrate W in the first transferring operation S20 or the second transferring operation S40 described above. For example, in the exemplary embodiment of the present invention, the substrate W may be transferred by using the third hand 320c in the third transferring operation S60. The first hand 320a may be a hand disposed at the topmost side among the plurality of hands 320. Since the substrate W to be transferred in the third transferring operation S60 is the substrate W that has been treated through the liquid treating operation S30 and the drying operation S50, the substrate W may be transferred using the hand 320a disposed at the topmost side to minimize contamination during the transfer process of the substrate W.

While the transfer unit 300 transfers the substrate W from the second process chamber 500 to the buffer chamber 200 in the third transferring operation S60, the weight of the substrate W placed on the hand 320 is measured. The weight of the substrate W measured in the third transferring operation S60 is the weight of the substrate W in the state in which the liquid film C is removed, which is completely dry-treated and unloaded from the second process chamber 500.

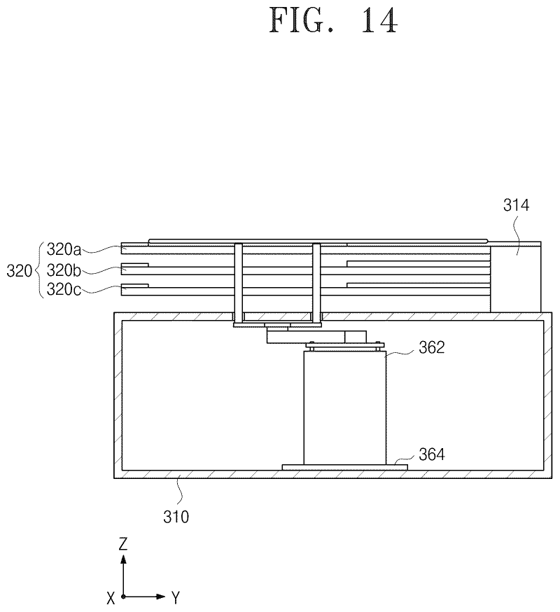

The weight measurement method is the same as that described above with reference to FIG. 10, and may be performed in the same manner as in the first transferring operation S20 or the second transferring operation S40. FIG. 14 is a diagram illustrating a shape of the transfer unit in the third transferring operation of FIG. 9.

Referring to FIG. 14, compared to FIG. 12 in which the weight of the substrate W is measured in the second transferring operation S40, there is a difference in that the liquid film C is not formed on the substrate W. Also, unlike the first transferring operation S20 in which the substrate W is supported and transferred by the second hand 320b or the second transferring operation S40 in which the substrate W is supported and transferred by the third hand 320c, the substrate W is supported and transferred by the first hand 320a in the third transferring operation S60 of the present exemplary embodiment. Accordingly, the distance at which the support protrusion 356b of the weight measuring unit 350 is required to be raised to support the substrate W may be different in the first transferring operation S20, the second transferring operation S40, and the third transferring operation S60.

The controller 30 may determine whether the liquid applied on the substrate W is entirely dried from the weight data of the substrate W measured by the weight measuring sensor 254 in the first transferring operation S20, the second transferring operation S40, and the third transferring operation S60.

Before the weight measurement for the substrate W is performed in the above-described transferring steps S20, S40, and S60, the weight measuring sensor 354 may perform an initialization process for the measured weight value. By initializing the weight value measured before the weight measurement is performed on the substrate W to adjust the zero point, it is possible to minimize an error that may occur due to long-term non-use or an error due to residual weight.

According to the above-described exemplary embodiment, the weight of the substrate W is measured in the substrate processing apparatus 1. For this reason, it is possible to measure the weight of the substrate W in the actual process atmosphere of processing the substrate W, and to detect an appropriate amount of the residual liquid on the substrate W during the process. For this reason, process defects may be prevented due to insufficient and excessive liquid.

According to the above-described exemplary embodiment, the weight measurement of the substrate W may be performed while the substrate W is being transferred. Therefore, there is no need to move to a separate space to measure the weight of the substrate W, so no additional time is required for the weight measurement process of the substrate W, so throughput may be increased and substrate processing efficiency may be increased. Although not described in the above-described exemplary embodiment, when the weight measurement value of the substrate W measured by the weight measuring unit 350 is out of a preset range or the weight of the liquid on the substrate W measured by the weight measuring unit 350 is out of a preset range, the substrate processing device 1 may be controlled to take measures, such as notification.

In the above exemplary embodiment, although it has been illustrated and described that the four support protrusions 356b of the weight measuring unit 350 are provided, the present invention is not limited thereto. The number of the plurality of support protrusions 356b and the arrangement relationship between the support protrusions 356b may be freely modified. The support protrusion 356b may be disposed at a position at which warpage due to its own weight of the substrate W may be minimized when supporting the bottom surface of the substrate W, and may be disposed so as not to collide or interfere with the hand 320 in a process in which the support protrusion 356b ascends and exchanges the substrate W with the hand 320.

In the above-described exemplary embodiment, the distance L2 between the pair of fingers 324 and 326 of the hand 320 is provided to be greater than the distance L1 between the two adjacent support protrusions 356b. However, when viewed from above, it is sufficient when the hand 320 and the support protrusions 356b are disposed not to overlap, and the distance L2 between the pair of fingers 324 and 326 of the hand 320 may be provided to be less than the distance L1 between the two adjacent support protrusions 356b.

In the above exemplary embodiment, the present invention has been described based on the case where the weight measuring sensor 354 includes the load cell 354a for measuring strain through a strain gauge, and the weight measuring sensor 354 is provided in the cantilever shape as an example. Alternatively, unlike this, the weight measuring sensor 354 may be provided as other known means capable of measuring weight, and the arrangement structure and shape thereof may also be freely changed.

In order to prevent the support protrusion 356b of the weight measuring unit 350 from interfering with the frame (not illustrated) of the base 310 when the support protrusion 356b of the weight measuring unit 350 ascends and descends to move between the weight measurement position and the standby position, the through hole 316 may be formed in the upper surface of the frame of the base 310. A configuration capable of preventing the support protrusion 356b of the weight measuring unit 350 from interfering with the upper surface of the frame of the base 310 when moving between the weight measurement position and the standby position is sufficient, and for example, the upper surface of the frame is composed of a shutter to be opened and closed, and the shutter of the upper surface of the frame may be opened when the support protrusion 356b of the weight measuring unit 350 ascends and descends.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A substrate processing apparatus comprising:
an index module including a load port and an index robot; and
a treating module including a transfer frame including a buffer for temporarily storing a substrate, a liquid treating chamber for liquid-treating a substrate, a drying chamber for removing the liquid remaining on the substrate, and a transfer unit for transferring the substrate between the buffer, the liquid treating chamber, and the drying chamber,
wherein the transfer unit includes:
a hand;
a weight measuring unit for measuring a weight of the substrate; and
a lifting driver configured to raise and lower the weight measuring unit relative to the hand.

2. The substrate processing apparatus of claim 1, wherein the weight measuring unit includes:
a support on which the substrate is placed;
a weight measuring sensor for measuring the weight of the substrate placed on the support; and
a measuring device base for supporting the weight measuring sensor.

3. The substrate processing apparatus of claim 2, wherein the support includes:
a bottom plate; and
a plurality of support protrusions protruding upward from the bottom plate and being in contact with a bottom surface of the substrate, and
the plurality of support protrusions is disposed to support the substrate at points spaced apart from each other.

4. The substrate processing apparatus of claim 3, wherein a distance between two support protrusions adjacent to each other among the plurality of support protrusions is smaller than a radius of the substrate.

5. The substrate processing apparatus of claim 3, wherein the transfer unit further includes a base, and
the base includes a frame having an inner space in which the weight measuring unit and the lifting driver are installed,
the lifting driver raises and lowers the weight measuring unit between a weight measurement position and a standby position,
the weight measurement position is where the weight measuring unit ascends and the support protrusions support the substrate, and
the standby position is a position where the support protrusion is disposed below the substrate supported by the hand.

6. The substrate processing apparatus of claim 5, wherein the hand includes a pair of fingers supporting an edge of the substrate, and
when the weight measuring unit moves from the standby position to the weight measurement position, the support protrusion and the finger are disposed so as not to interfere with each other.

7. The substrate processing apparatus of claim 5, wherein a plurality of through holes are formed on an upper surface of the frame, and
the plurality of through holes are respectively provided at points corresponding to the plurality of support protrusions when viewed from above.

8. The substrate processing apparatus of claim 1, wherein the transfer frame further includes a fan unit that generates descending airflow in a transfer region therein, and
the transfer unit further includes an airflow blocking plate disposed above the hand to block the descending airflow from reaching the substrate.

9. The substrate processing apparatus of claim 5, further comprising:
a controller,
the controller controls the weight measuring unit to measure the weight of the substrate while the transfer unit transfers the substrate, and
the weight measurement of the substrate is performed in a state where the weight measuring unit ascends from the standby position to the weight measurement position, the weight measuring unit takes over the substrate supported by the hand, and the support supports the substrate.

10. The substrate processing apparatus of claim 9, wherein the controller controls the transfer unit to measure the weight of the substrate before the substrate is loaded into the liquid treating chamber, and
measure the weight of the substrate after the substrate is unloaded from the liquid treating chamber.

11. The substrate processing apparatus of claim 10, wherein the substrate unloaded from the liquid treating chamber is a substrate on which a liquid film is formed.

12.-18. (canceled)

19. A substrate processing apparatus comprising:
an index module including a load port and an index robot; and
a treating module including a transfer frame including a buffer for temporarily storing a substrate, a liquid treating chamber for liquid-treating a substrate, a drying chamber for removing a liquid remaining on the substrate, and a transfer unit for transferring the substrates between the buffer, the liquid treating chamber, and the drying chamber; and
a controller,
wherein the transfer frame further includes a fan unit that generates descending airflow in a transfer region therein,
the transfer unit includes:
a base including a frame provided with an inner space;
hands installed to be vertically spaced apart from each other on an upper portion of the base to advance and retract based on the base;
a weight measuring unit installed in the inner space of the base and measuring the weight of the substrate;
a lifting driver installed in the inner space of the base to move up and down the weight measuring unit; and
an airflow blocking plate placed above the hand to minimize the descending airflow from reaching the substrate,
the weight measuring unit includes:
a support on which the substrate is placed;
a weight measuring sensor for measuring the weight of the substrate placed on the support; and
a measuring device base for supporting the weight measuring sensor,
the support includes:
a bottom plate; and
a plurality of support protrusions protruding upward from the bottom plate and being in contact with a bottom surface of the substrate,
the plurality of support protrusions is disposed to support the substrate at points spaced apart from each other,
a distance between two support protrusions adjacent to each other among the plurality of support protrusions is smaller than a radius of the substrate,
the frame includes a plurality of through holes formed on an upper surface of the frame,
the plurality of through holes are respectively provided at points corresponding to the plurality of support protrusions when viewed from above,
the controller controls the lifting driver to move up and down the weight measuring unit between a weight measurement position and a standby position,
the weight measurement position is a position where the weight measuring unit ascends and the support protrusion supports the substrate, and
the standby position is a position where the support protrusion is disposed below the substrate supported by the hand.

20. The substrate processing apparatus of claim 19,
wherein the controller is configured to control the weight measuring unit to measure the weight of the substrate when the transfer unit transfers the substrate,
control the transfer unit to measure the weight of the substrate before the substrate is loaded into the liquid treating chamber, and
measure the weight of the substrate after the substrate is unloaded from the liquid treating chamber, and
wherein the weight measurement of the substrate is performed by taking over, by the weight measuring unit, the substrate supported by the hand while ascending from the standby position to the weight measurement position.
